(19) United States
(12) Patent Application Publication
(10) Pub. No.: US 2025/0212419 A1
(43) Pub. Date: Jun. 26, 2025

(54) MAGNETIC MEMORY DEVICE

(71) Applicant: SAMSUNG ELECTRONICS CO., LTD., Suwon-si (KR)

(72) Inventors: Stuart Papworth Parkin, Halle (DE); Andrea Migliorini, Halle (DE); Jaechun Jeon, Halle (DE); Ung Hwan Pi, Suwon-si (KR)

(73) Assignee: Max-Planck-Gesellschaft zur Förderung der Wissenschaften e.V., München (DE)

(21) Appl. No.: 18/941,866

(22) Filed: Nov. 8, 2024

(30) Foreign Application Priority Data
Dec. 21, 2023 (KR) 10-2023-0187935

(51) Int. Cl. H10B 61/00; G01R 33/07; H10N 50/10; H10N 50/20

(52) U.S. Cl. CPC H10B 61/00; G01R 33/075; H10N 50/20; H10N 50/10

(57) ABSTRACT

A magnetic memory device includes a conductive line extended in a first direction and a magnetic track line provided on a top surface of the conductive line and extended in the first direction. The magnetic track line includes a domain injection portion and a line portion, which is extended from the domain injection portion in the first direction. The domain injection portion has a tapered shape in an opposite direction of the first direction. The conductive line has a linewidth in a second direction, and the first and second directions are parallel to the top surface of the conductive line and are perpendicular to each other. Below the domain injection portion, a first linewidth of the conductive line remains constant in the opposite direction of the first direction.

### CROSS-REFERENCE TO RELATED APPLICATIONS

This application claims priority under 35 U.S.C. § 119 to Korean Patent Application No. 10-2023-0187935, filed on Dec. 21, 2023, in the Korean Intellectual Property Office, the entire contents of which are hereby incorporated by reference.

### BACKGROUND OF THE INVENTION

Due to the increased demand for electronic devices with a fast speed and/or a low power consumption, memory devices embedded in the electronic devices require a fast operating speed and/or a low operating voltage. A magnetic memory device is being developed to meet such a demand. The magnetic memory device has technical advantages, such as reduced latency and/or non-volatility and are emerging as next-generation memory devices. Recently, a new magnetic domain memory device exploiting movement of magnetic domain walls are being researched and developed.

The magnetic domain memory device has a magnetic track line including a plurality of magnetic domains, and the direction of the movement of the magnetic domains in the magnetic track line is changed depending on the direction of a current. A writing device, which is provided adjacent to the magnetic track line, is used to write data in the magnetic domains. An additional line generating a magnetic field or a magnetic tunnel junction device for spin torque injection may be used as the writing device.

### SUMMARY

In general, in some aspects, the present disclosure is directed toward magnetic memory devices, including magnetic memory devices configured to perform a writing operation on a domain in a magnetic track line, without a writing device. Implementations of the magnetic memory devices may allow easy and stable writing operations on the domain in the magnetic track line.

According to some aspects, the present disclosure is directed to magnetic memory devices that include a conductive line extended in a first direction and a magnetic track line provided on a top surface of the conductive line and extended in the first direction. The magnetic track line may include a domain injection portion and a line portion, which is extended from the domain injection portion in the first direction. The domain injection portion may have a tapered shape in an opposite direction of the first direction. The conductive line may have a linewidth in a second direction, and the first and second directions may be parallel to the top surface of the conductive line and may be perpendicular to each other. Below the domain injection portion, a first linewidth of the conductive line may remain constant in the opposite direction of the first direction.

According to some aspects, the present disclosure is directed to magnetic memory devices that include a conductive line extended in a first direction, and a magnetic track line provided on a top surface of the conductive line and extended in the first direction. The magnetic track line may include a domain injection portion and a line portion, which is extended from the domain injection portion in the first direction. The magnetic track line may have a width in a second direction, and the first and second directions may be parallel to the top surface of the conductive line and may be perpendicular to each other. A first width of the domain injection portion may decrease as a distance from the line portion increases. The conductive line may have a linewidth in the second direction. Below the domain injection portion, a first linewidth of the conductive line may be larger than the first width of the domain injection portion.

### BRIEF DESCRIPTION OF THE DRAWINGS

Example implementations will be more clearly understood from the following detailed description, taken in conjunction with the accompanying drawings.

FIG. 1 is a perspective view schematically illustrating an example of a magnetic memory device according to some implementations.

FIG. 2 is a plan view illustrating the magnetic memory device of FIG. 1 according to some implementations.

FIG. 3 is a cross-sectional view taken along line A-A′ of FIG. 2 according to some implementations.

FIGS. 4A, 5A, 6A, 7A, 8A, and 9A are cross-sectional views taken along line A-A′ of FIG. 2 illustrating an example of a writing operation on a magnetic memory device according to some implementations.

FIG. 4B is a graph showing a change in an example of a cross-section area of a conductive line and a magnetic track line of FIG. 4A according to some implementations.

FIG. 4C is a graph showing an example of a current density of a current applied through the conductive line of FIG. 4A according to some implementations.

FIGS. 5B, 6B, 7B, 8B, and 9B are graphs showing examples of current densities of currents applied through conductive lines of FIGS. 5A, 6A, 7A, 8A, and 9A, respectively, according to some implementations.

FIG. 10 is a cross-sectional view taken along line A-A′ of FIG. 2 showing an example of a magnetic memory device according to some implementations.

FIG. 11 is a cross-sectional view taken along line A-A′ of FIG. 2 showing an example of a magnetic memory device according to some implementations.

FIG. 12 is a plan view illustrating an example of a magnetic memory device according to some implementations.

FIG. 13 is an enlarged view illustrating an example of a portion ‘R1’ of FIG. 12 according to some implementations.

FIG. 14 is a plan view illustrating an example of a magnetic memory device according to some implementations.

FIG. 15 is an enlarged view illustrating an example of a portion ‘R2’ of FIG. 14 according to some implementations.

FIG. 16 is a plan view illustrating an example of a magnetic memory device according to some implementations.

FIGS. 17 to 21 are perspective views schematically illustrating an example of a method of fabricating a magnetic memory device according to some implementations.

### DETAILED DESCRIPTION

Hereinafter, example implementations will be explained in detail with reference to the accompanying drawings.

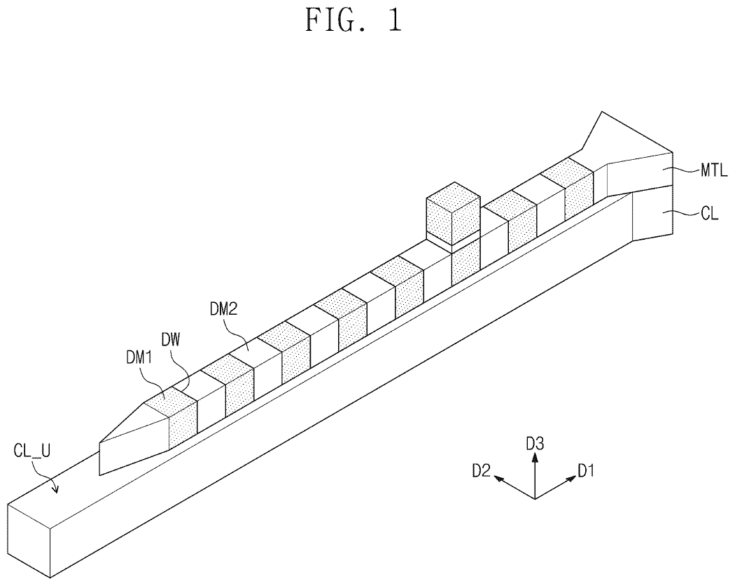

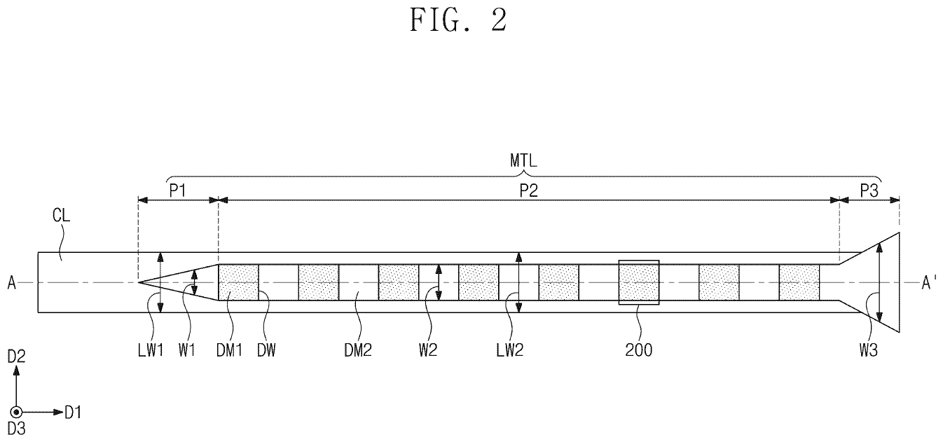

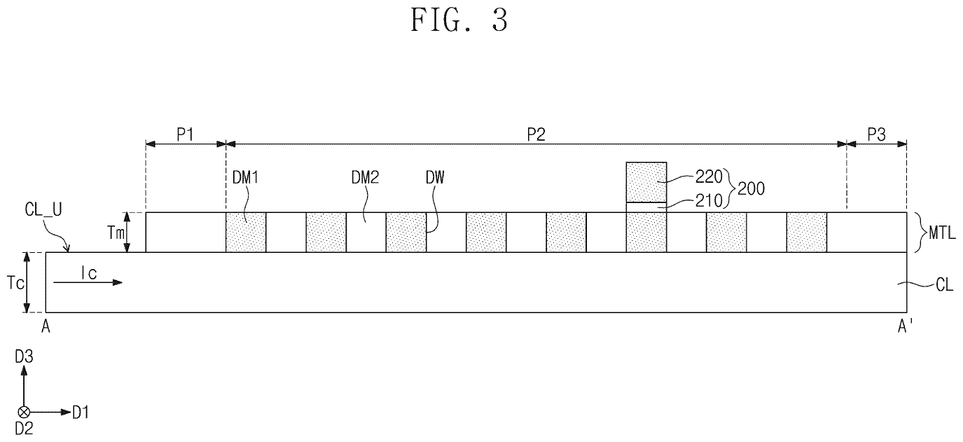

FIG. 1 is a perspective view schematically illustrating an example of a magnetic memory device according to some implementations. FIG. 2 is a plan view illustrating the magnetic memory device of FIG. 1 according to some implementations, and FIG. 3 is a cross-sectional view taken along line A-A′ of FIG. 2 according to some implementations.

In FIGS. 1 to 3, the magnetic memory device may include a conductive line CL, a magnetic track line MTL on the conductive line CL, and a reading device 200 on the magnetic track line MTL. The magnetic track line MTL may be disposed on a top surface CL_U of the conductive line CL, and the conductive line CL and the magnetic track line MTL may be elongated in a first direction D1, which is parallel to the top surface CL_U of the conductive line CL.

The magnetic track line MTL may include a domain injection portion P1 and a line portion P2, which is extended from the domain injection portion P1 in the first direction D1. A magnetic domain with a specific magnetization direction may be injected into the magnetic track line MTL through the domain injection portion P1, and the injected magnetic domain may be stored in and moved through the line portion P2. In some implementations, the magnetic track line MTL may further include an end portion P3, which is extended from the line portion P2 in the first direction D1. The movement of the magnetic domain may be stopped in the end portion P3. The domain injection portion P1 and the end portion P3 may be spaced apart from each other in the first direction D1, with the line portion P2 interposed therebetween. The domain injection portion P1 may be connected to an end of the line portion P2, and the end portion P3 may be connected to an opposite end of the line portion P2. The end of the line portion P2 and the opposite end of the line portion P2 may be opposite to each other in the first direction D1. The magnetic track line MTL may include at least one of magnetic elements (e.g., cobalt (Co), iron (Fe), and nickel (Ni)).

The magnetic track line MTL may have a width in a second direction D2, which is parallel to the top surface CL_U of the conductive line CL and is perpendicular to the first direction D1. A first width W1 of the domain injection portion P1 in the second direction D2 may decrease as a distance from the line portion P2 increases. The first width W1 of the domain injection portion P1 may decrease in an opposite direction of the first direction D1. The domain injection portion P1 may have a tapered shape in the opposite direction of the first direction D1. A second width W2 of the line portion P2 in the second direction D2 may remain constant in the first direction D1. The line portion P2 may have a constant width (i.e., the second width W2), between the domain injection portion P1 and the end portion P3. The second width W2 of the line portion P2 may be larger than the first width W1 of the domain injection portion P1. A third width W3 of the end portion P3 in the second direction D2 may increases as a distance from the line portion P2 increases. The third width W3 of the end portion P3 may increase in the first direction D1. The third width W3 of the end portion P3 may be larger than the second width W2 of the line portion P2.

The line portion P2 of the magnetic track line MTL may include a plurality of domains DM1 and DM2, which are arranged in the first direction D1, and domain walls DW between the domains DM1 and DM2. Each of the domains DM1 and DM2 may be a region, which is placed in the magnetic track line MTL and has a magnetic moment aligned to a specific direction, and each of the domain walls DW may be a region where the direction of a magnetic moment varies between the domains DM1 and DM2. The domains DM1 and DM2 and the domain walls DW may be alternately arranged in the first direction D1. The domains DM1 and DM2 may include a first domain DM1 and a second domain DM2, which are adjacent to each other, and a magnetization direction of the first domain DM1 may be opposite to a magnetization direction of the second domain DM2. Each of the domain walls DW may define a boundary between the first and second domains DM1 and DM2, which have magnetization directions opposite to each other.

The conductive line CL may be configured to produce a spin orbit torque by a current Ic passing through the conductive line CL. The conductive line CL may be formed of or include a material, which can produce a spin Hall effect or a Rashba effect by a current flowing through the conductive line CL in the first direction D1 (or the opposite direction of the first direction D1). The conductive line CL may include heavy metals with an atomic number of 30 or higher and may include at least one of iridium (Ir), ruthenium (Ru), tantalum (Ta), platinum (Pt), palladium (Pd), bismuth (Bi), titanium (Ti), tungsten (W), beta-tantalum (β-Ta), and beta-tungsten (β-W).

The conductive line CL may have a linewidth in the second direction D2. The conductive line CL below the domain injection portion P1 may have a first linewidth LW1. The first linewidth LW1 of the conductive line CL may be remain constant in the first direction D1 (or the opposite direction of the first direction D1). The first linewidth LW1 of the conductive line CL may be larger than the first width W1 of the domain injection portion P1. The conductive line CL below the line portion P2 may have a second linewidth LW2. The second linewidth LW2 of the conductive line CL may remain constant in the first direction D1 (or in the opposite direction of the first direction D1). The first linewidth LW1 and the second linewidth LW2 may be substantially equal to each other. The first linewidth LW1 and the second linewidth LW2 may be larger than or equal to the second width W2 of the line portion P2.

The magnetic track line MTL may have a thickness Tm in a third direction D3, which is perpendicular to the top surface CL_U of the conductive line CL. The thickness Tm of the magnetic track line MTL may remain constant in the first direction D1. The thickness Tm of the domain injection portion P1, the thickness Tm of the line portion P2, and the thickness Tm of the end portion P3 may be substantially equal to each other.

The conductive line CL may have a thickness Tc in the third direction D3, and the thickness Tc of the conductive line CL may remain constant in the first direction D1. The thickness Tc of the conductive line CL below the domain injection portion P1 may be equal to the thickness Tc of the conductive line CL below the line portion P2 and may be equal to the thickness Tc of the conductive line CL below the end portion P3.

The reading device 200 may be disposed on the line portion P2 of the magnetic track line MTL. The reading device 200 may be overlapped with a corresponding one of the domains DM1 and DM2 vertically (e.g., in the third direction D3) and may be configured to read out a bit written in the corresponding domain DM1 or DM2. The reading device 200 may include a GMR sensor using a giant magneto resistance effect, a TMR sensor using a tunnel magneto resistance effect, or an AMR sensor using an anisotropy magneto resistance.

In an embodiment, the reading device 200 may include a magnetic pattern 220 on the line portion P2 and a non-magnetic pattern 210 between the magnetic pattern 220 and the line portion P2. The magnetic pattern 220 may include at least one of cobalt (Co), iron (Fe), and nickel (Ni). The non-magnetic pattern 210 may include at least one of non-magnetic metal oxide materials (e.g., magnesium oxide, titanium oxide, aluminum oxide, magnesium-zinc oxide, or magnesium-boron oxide).

The reading device 200 may be overlapped with a corresponding one of the domains DM1 and DM2 vertically (e.g., in the third direction D3), and the magnetic pattern 220, the non-magnetic pattern 210, and the corresponding domain DM1 or DM2 may constitute a magnetic tunnel junction. By applying a current, which flows in a direction perpendicular to an interface between the magnetic pattern 220 and the non-magnetic pattern 210, to the reading device 200, it may be possible to obtain information on a resistance state (e.g., high or low resistance state) of the magnetic tunnel junction. The information on the resistance state obtained by the reading device 200 may correspond to a bit written in the corresponding domain DM1 or DM2.

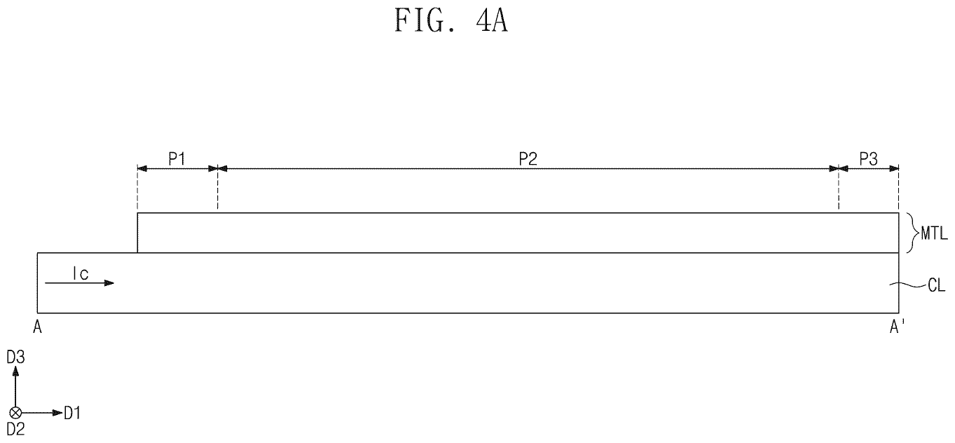

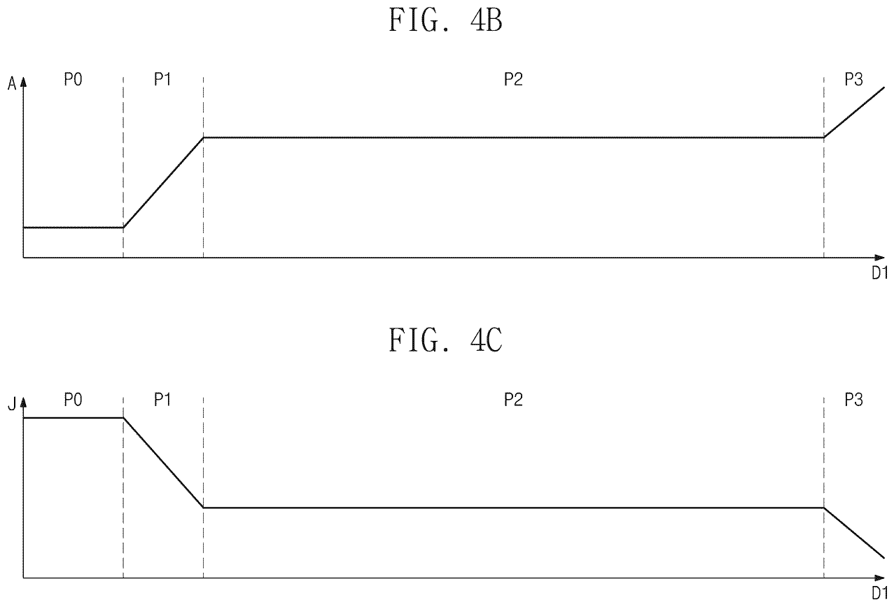

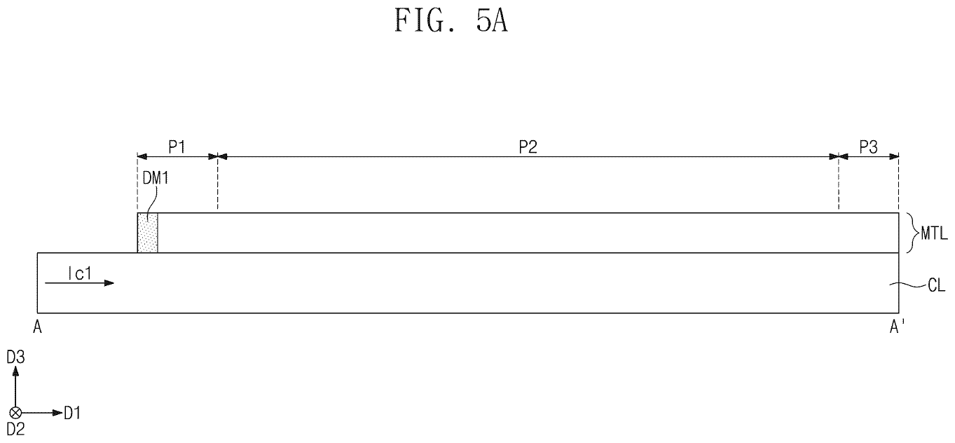

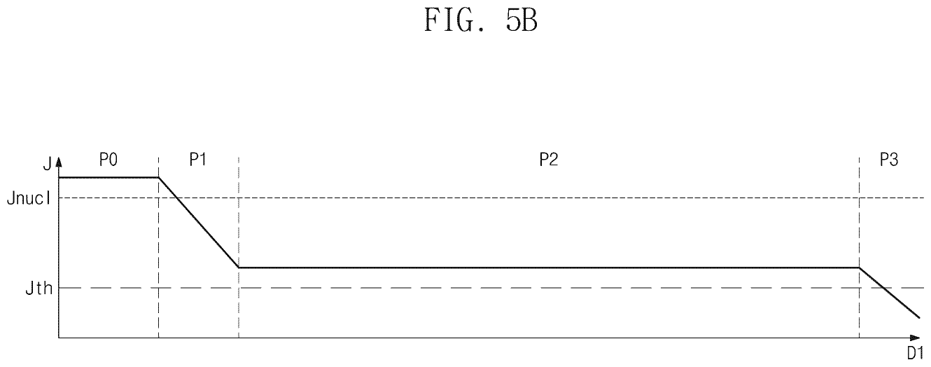

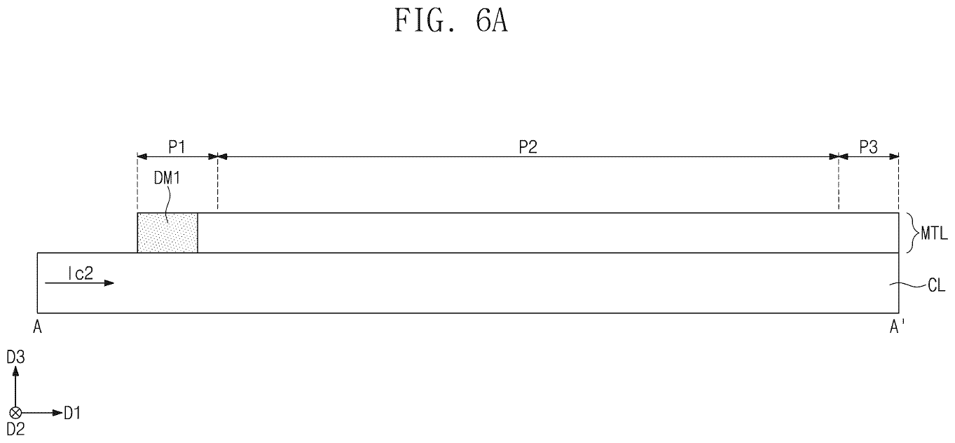

FIGS. 4A, 5A, 6A, 7A, 8A, and 9A are cross-sectional views taken along line A-A′ of FIG. 2 showing an example of a writing operation on a magnetic memory device according to some implementations. FIG. 4B is a graph showing a change in a cross-section area of examples of a conductive line and a magnetic track line of FIG. 4A according to some implementations, and FIG. 4C is a graph showing an example of a current density of a current applied through the conductive line of FIG. 4A according to some implementations. FIGS. 5B, 6B, 7B, 8B, and 9B are graphs showing examples of current densities of currents applied through conductive lines of FIGS. 5A, 6A, 7A, 8A, and 9A, respectively, according to some implementations. For simplification, the reading device of FIG. 2 is omitted from FIGS. 4A, 5A, 6A, 7A, 8A, and 9A.

In FIGS. 2, 4A, and 4B, the conductive line CL and the magnetic track line MTL may have a cross-section that is parallel to the second and third directions D2 and D3. Since the conductive line CL and the magnetic track line MTL are extended in the first direction D1, the cross-section area A of the conductive line CL and the magnetic track line MTL may vary in the first direction D1, as shown in FIG. 4B.

In FIG. 4B, a region P0 illustrates a cross-section area A of the conductive line CL. Referring to the region P0 of FIG. 4B, the cross-section area A of the conductive line CL may remain constant in the first direction D1. In FIG. 4B, a region P1 illustrates a cross-section area A of the domain injection portion P1 of the magnetic track line MTL and the conductive line CL below the domain injection portion P1. Referring to the region P1 of FIG. 4B, since the first width W1 of the domain injection portion P1 increases as a distance to the line portion P2 of the magnetic track line MTL decreases, the cross-section area A of the domain injection portion P1 and the conductive line CL below the domain injection portion P1 may increase in the first direction D1. In FIG. 4B, a region P2 illustrates a cross-section area A of the line portion P2 of the magnetic track line MTL and the conductive line CL below the line portion P2. Referring to the region P2 of FIG. 4B, since the line portion P2 has a constant width (i.e., the second width W2), the cross-section area A of the line portion P2 and the conductive line CL below the line portion P2 may remain constant in the first direction D1. In FIG. 4B, a region P3 illustrates a cross-section area A of the end portion P3 of the magnetic track line MTL and the conductive line CL below the end portion P3. Referring to the region P3 of FIG. 4B, since the third width W3 of the end portion P3 increases as a distance from the line portion P2 increases, the cross-section area A of the end portion P3 and the conductive line CL below the end portion P3 may increases in the first direction D1.

In FIGS. 4A to 4C, a current Ic applied to the conductive line CL may flow through the conductive line CL and the magnetic track line MTL, and a current density J of the current Ic may be inversely proportional to a cross-section area A of the conductive line CL and the magnetic track line MTL. In FIG. 4C, a region P0 illustrates the current density J of the current Ic applied to the conductive line CL. Referring to the region P0 of FIG. 4C, the current density J may remain constant in the first direction D1. In FIG. 4C, a region P1 illustrates the current density J of the current Ic flowing through the domain injection portion P1 of the magnetic track line MTL and the conductive line CL. As shown in FIG. 4B, the cross-section area A of the domain injection portion P1 and the conductive line CL below the domain injection portion P1 may increase in the first direction D1, and thus, referring to the region P1 of FIG. 4C, the current density J may decrease in the first direction D1. In FIG. 4C, a region P2 illustrates the current density J of the current Ic flowing through the line portion P2 of the magnetic track line MTL and the conductive line CL. As shown in FIG. 4B, the cross-section area A of the line portion P2 and the conductive line CL below the line portion P2 may remain constant in the first direction D1, and thus, as shown in the region P2 of FIG. 4C, the current density J may remain constant in the first direction D1. In FIG. 4C, a region P3 illustrates the current density J of the current Ic flowing through the end portion P3 of the magnetic track line MTL and the conductive line CL. As shown in FIG. 4B, the cross-section area A of the end portion P3 and the conductive line CL below the end portion P3 may increase in the first direction D1, and thus, as shown in the region P3 of FIG. 4C, the current density J may decrease in the first direction D1.

In FIGS. 5A and 5B, a first current Ic1 may be applied to the conductive line CL, and a current density J of the first current Ic1 may be greater than a critical current density Jnucl, which is required for domain formation (i.e., J>Jnucl). The current density J of the first current Ic1 may be greater than the critical current density Jnucl at the end portion of the domain injection portion P1 of the magnetic track line MTL, and as a distance to the line portion P2 of the magnetic track line MTL in the first direction D1 decreases, it may decrease to be smaller than the critical current density Jnucl. Accordingly, a first domain DM1, which has the same or aligned magnetization direction, may be formed at the end portion of the domain injection portion P1 of the magnetic track line MTL.

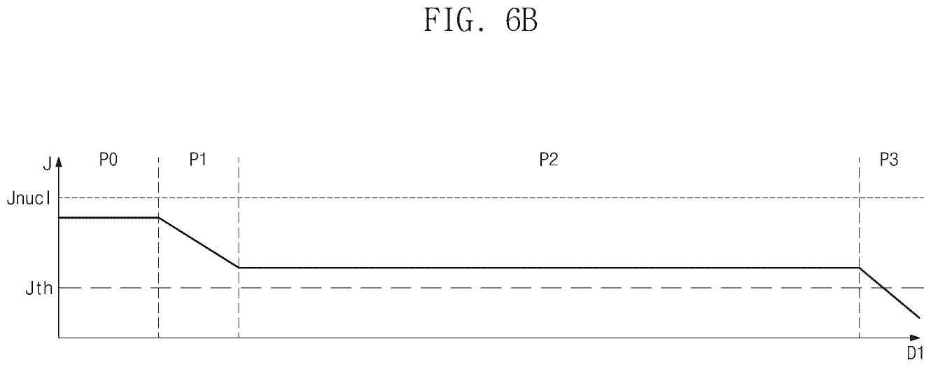

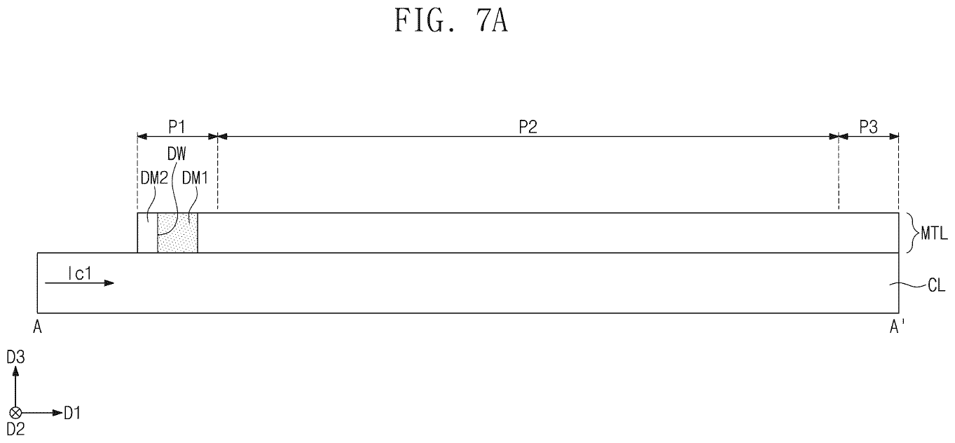

In FIGS. 6A and 6B, a second current Ic2 may be applied to the conductive line CL, and a current density J of the second current Ic2 may be smaller than the critical current density Jnucl for the domain formation and may be greater than a threshold current density Jth for domain movement (i.e., Jth<J<Jnucl). Accordingly, the first domain DM1 may be moved in the first direction D1, without the domain formation in the domain injection portion P1 of the magnetic track line MTL.

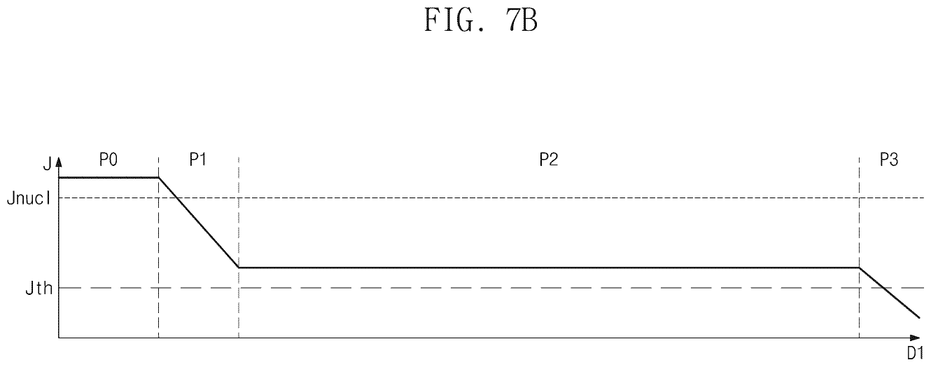

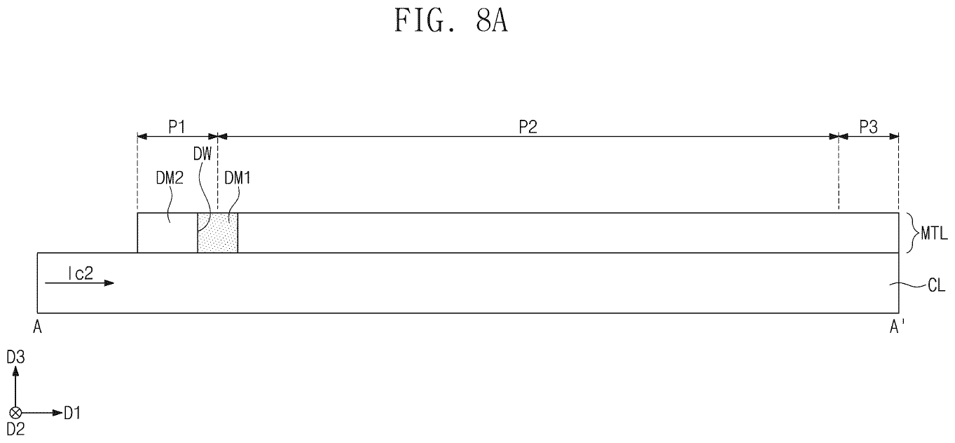

In FIGS. 7A and 7B, the first current Ic1 may be applied to the conductive line CL again. A current density J of the first current Ic1 may be greater than the critical current density Jnucl at the end portion of the domain injection portion P1 of the magnetic track line MTL and may decrease to be smaller than the critical current density Jnucl, as a distance to the line portion P2 of the magnetic track line MTL in the first direction D1 decreases. Accordingly, a second domain DM2, which has the same or aligned magnetization direction, may be formed at the end portion of the domain injection portion P1 of the magnetic track line MTL. The magnetization direction of the second domain DM2 may be an opposite direction to the magnetization direction of the first domain DM1. A domain wall DW may be formed between the first domain DM1 and the second domain DM2.

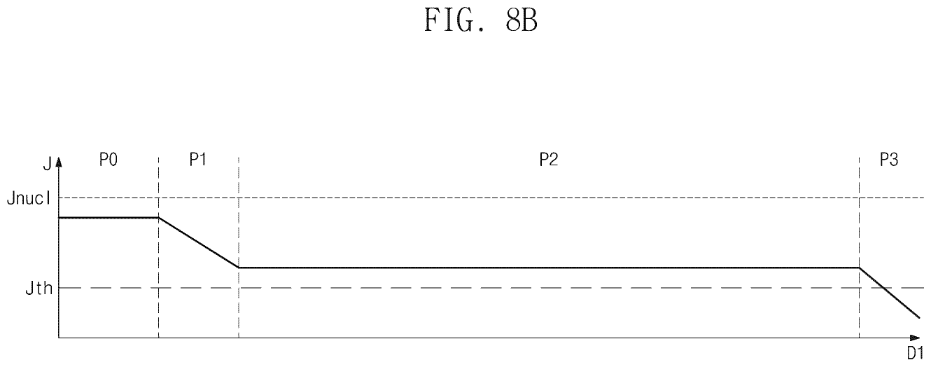

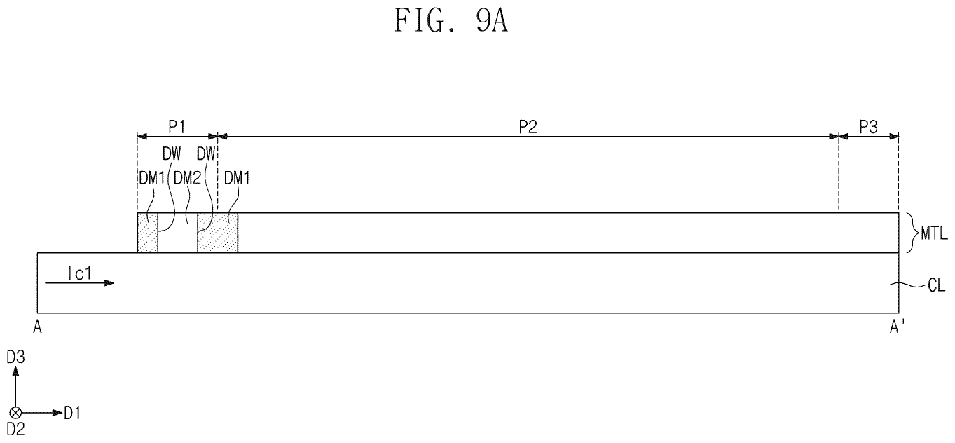

In FIGS. 8A and 8B, the second current Ic2 may be applied to the conductive line CL again. Accordingly, the first and second domains DM1 and DM2 may be moved in the first direction D1, while a domain is not formed at the domain injection portion P1 of the magnetic track line MTL.

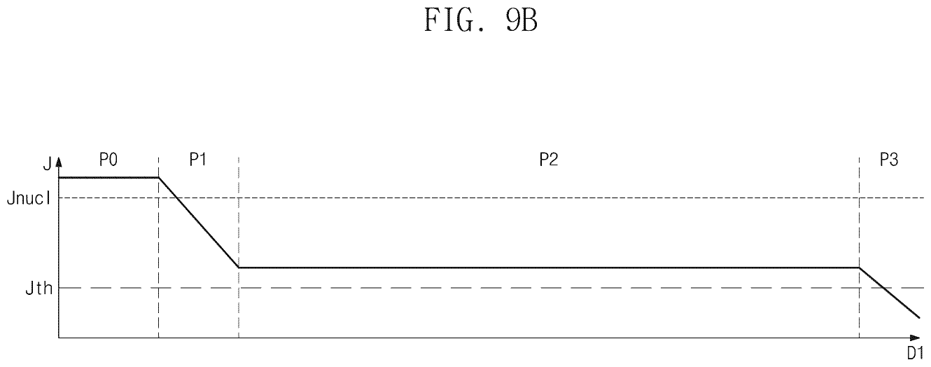

In FIGS. 9A and 9B, the first current Ic1 may be applied to the conductive line CL again. A current density J of the first current Ic1 may be greater than the critical current density Jnucl at the end portion of the domain injection portion P1 of the magnetic track line MTL and may decrease to be smaller than the critical current density Jnucl, as a distance to the line portion P2 of the magnetic track line MTL in the first direction D1 decreases. Accordingly, an additional first domain DM1, which has the same or aligned magnetization direction, may be formed at the end portion of the domain injection portion P1 of the magnetic track line MTL. The magnetization direction of the additional first domain DM1 may be opposite to the magnetization direction of the second domain DM2 and may be the same as the magnetization direction of the first domain DM1. An additional domain wall DW may be formed between the additional first domain DM1 and the second domain DM2.

The first current Ic1 may be a writing current, which is used to form a domain in the domain injection portion P1 of the magnetic track line MTL, and the second current Ic2 may be a moving current, which is used to move the domain in the magnetic track line MTL. Since the first current Ic1 and the second current Ic2 are alternately applied to the conductive line CL, the first and second domains DM1 and DM2 may be formed in the domain injection portion P1 of the magnetic track line MTL and may be moved to the line portion P2 of the magnetic track line MTL.

In FIG. 3, the first and second domains DM1 and DM2 may be stored in the line portion P2 of the magnetic track line MTL. In the case where the second current Ic2 is applied to the conductive line CL, the first and second domains DM1 and DM2 in the line portion P2 may be moved toward the end portion P3. In the end portion P3 of the magnetic track line MTL, the current density J may be reduced to be smaller than the threshold current density (Jth), as shown in FIGS. 5B, 6B, 7B, 8B, and 9B. Accordingly, the movement of the first and second domains DM1 and DM2 may be stopped in the end portion P3 of the magnetic track line MTL. In this case, by successively applying the second current Ic2 to the conductive line CL, it may be possible to make the first and second domains DM1 and DM2 in the magnetic track line MTL have the same magnetization direction. This operation may be used as an erase operation on a magnetic memory device according to an embodiment of the inventive concept.

According to some implementations, the magnetic track line MTL may include the domain injection portion P1, which has a tapered shape in the opposite direction of the first direction D1, and the line portion P2, which is extended from the domain injection portion P1 in the first direction D1. Accordingly, the cross-section area A of the domain injection portion P1 and the conductive line CL below the domain injection portion P1 may increase as a distance to the line portion P2 of the magnetic track line MTL decreases (i.e., in the first direction D1). If the first current Ic1, whose current density is greater than the critical current density Jnucl, is applied to the conductive line CL, the current density J of the first current Ic1 may be greater than the critical current density Jnucl at an end portion of the domain injection portion P1, and as a distance to the line portion P2 of the magnetic track line MTL (e.g., in the first direction D1) decreases, it may be reduced to be smaller than the critical current density Jnucl. Accordingly, a domain, which has the same or aligned magnetization direction, may be formed at the end portion of the domain injection portion P1 of the magnetic track line MTL.

According to some implementations, the domain formation in the magnetic track line MTL (i.e., the writing operation) may be performed by repeatedly applying the first current Ic1 to the conductive line CL, without any additional conductive line for the domain formation or any writing device. Accordingly, the writing operation for the domain formation in the magnetic track line MTL may be possible, without an additional conductive line or a writing device, and the magnetic memory device may be configured to allow an easy and stable writing operation for the domain formation in the magnetic track line MTL.

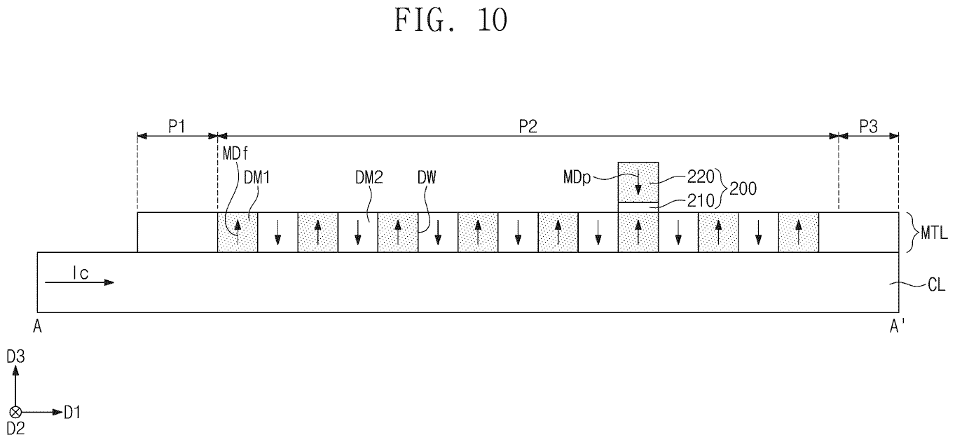

FIG. 10 is a cross-sectional view taken along line A-A′ of FIG. 2 showing an example of a magnetic memory device according to some implementations. For brevity, the same element as that in the magnetic memory device described with reference to FIGS. 1 to 3 may be identified by the same reference number without repeating an overlapping description.

In FIG. 10, the magnetic track line MTL may have a perpendicular magnetic anisotropy. Each of the domains DM1 and DM2 may have a magnetization direction MDf, which is perpendicular to an interface between the conductive line CL and the magnetic track line MTL. The domains DM1 and DM2 may include a first domain DM1 and a second domain DM2, which are adjacent to each other, and here, the magnetization direction MDf of the first domain DM1 may be opposite to the magnetization direction MDf of the second domain DM2.

The magnetic pattern 220 may have a perpendicular magnetic anisotropy (PMA). The magnetic pattern 220 may have a magnetization direction MDp, which is perpendicular to an interface between the magnetic pattern 220 and the non-magnetic pattern 210, and the magnetization direction MDp of the magnetic pattern 220 may be fixed to a specific direction. The magnetic pattern 220, the non-magnetic pattern 210, and a corresponding domain DM1 or DM2 may constitute a magnetic tunnel junction, and the non-magnetic pattern 210 may be referred to as a tunnel barrier pattern.

The magnetic track line MTL and the magnetic pattern 220 may include at least one of i) perpendicular magnetic materials (e.g., CoFeTb, CoFeGd, and CoFeDy), ii) perpendicular magnetic materials with L10 structure, iii) CoPt-based materials with hexagonal-close-packed structure, or iv) perpendicular magnetic structures. The perpendicular magnetic material with the L10 structure may include at least one of L10 FePt, L10 FePd, L10 CoPd, or L10 CoPt. The perpendicular magnetic structures may include magnetic and non-magnetic layers that are alternatingly and repeatedly stacked. For example, the perpendicular magnetic structures may include at least one of (Co/Pt)n, (CoFe/Pt)n, (CoFe/Pd)n, (Co/Pd)n, (Co/Ni)n, (CoNi/Pt)n, (CoCr/Pt)n or (CoCr/Pd)n, where n is the number of pairs of the stacked layers. The magnetic track line MTL and the magnetic pattern 220 may be formed of or include at least one of CoFeB or Co-based Heusler alloys.

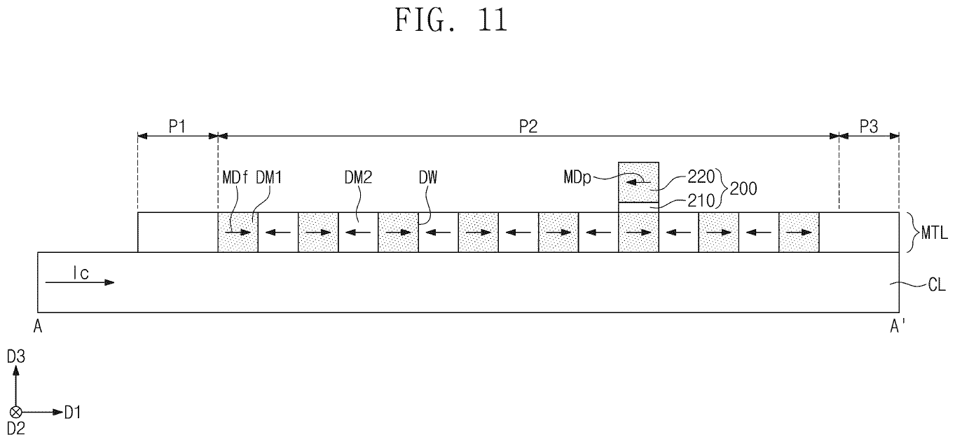

FIG. 11 is a cross-sectional view along line A-A′ of FIG. 2 showing an example of a magnetic memory device according to some implementations. For brevity, the same element as that in the magnetic memory device described with reference to FIGS. 1 to 3 may be identified by the same reference number without repeating an overlapping description.

In FIG. 11, the magnetic track line MTL may have an in-plane magnetic anisotropy (IMA). Each of the domains DM1 and DM2 may have a magnetization direction MDf, which is parallel to an interface between the conductive line CL and the magnetic track line MTL. The domains DM1 and DM2 may include a first domain DM1 and a second domain DM2, which are adjacent to each other, and here, the magnetization direction MDf of the first domain DM1 may be opposite to the magnetization direction MDf of the second domain DM2.

The magnetic pattern 220 may have an in-plane magnetic anisotropy (IMA). The magnetic pattern 220 may have a magnetization direction MDp, which is parallel to an interface between the magnetic pattern 220 and the non-magnetic pattern 210, and the magnetization direction MDp of the magnetic pattern 220 may be fixed to a specific direction. The magnetic pattern 220, the non-magnetic pattern 210, and a corresponding domain DM1 or DM2 may constitute a magnetic tunnel junction, and the non-magnetic pattern 210 may be referred to as a tunnel barrier pattern.

The magnetic track line MTL and the magnetic pattern 220 may include ferromagnetic materials, respectively, and the magnetic pattern 220 may further include an antiferromagnetic material, which is used to fix a magnetization direction of the ferromagnetic material.

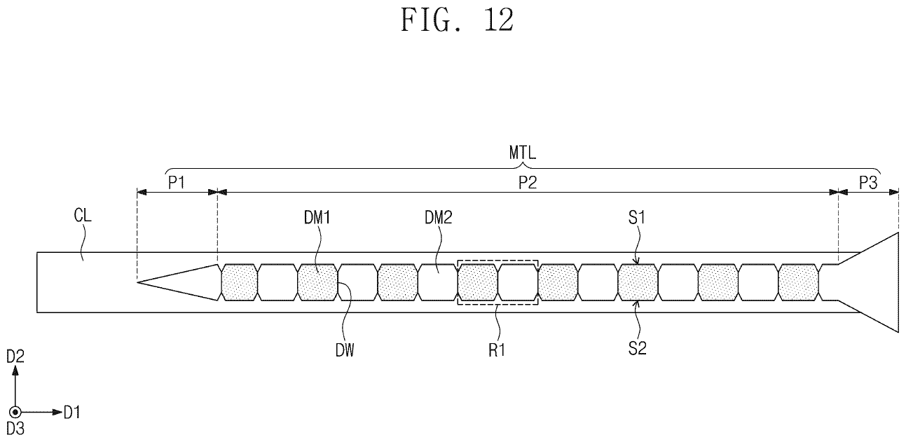

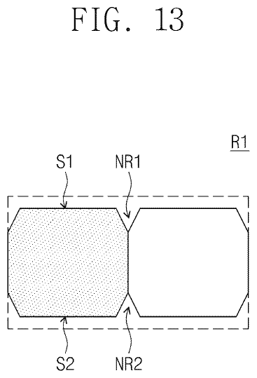

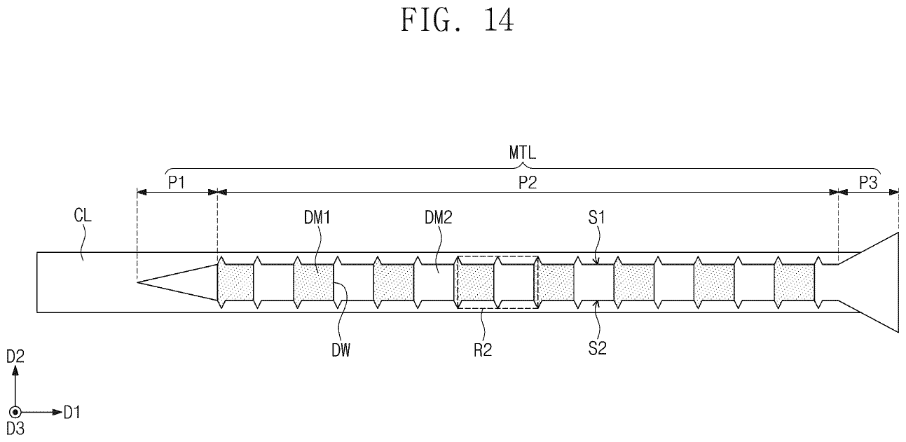

FIG. 12 is a plan view illustrating an example of a magnetic memory device according to some implementations, and FIG. 13 is an enlarged view illustrating an example of a portion ‘R1’ of FIG. 12 according to some implementations. For brevity, features, which are different from the magnetic memory device described with reference to FIGS. 1 to 3, will be mainly described below.

In FIGS. 12 and 13, the line portion P2 of the magnetic track line MTL may have a first side surface S1 and a second side surface S2, which face each other in the second direction D2. The first side surface S1 may include first recess regions NR1, which are recessed from the first side surface S1 into the line portion P2 and are spaced apart from each other in the first direction D1. The second side surface S2 may include second recess regions NR2, which are recessed from the second side surface S2 into the line portion P2 and are spaced apart from each other in the first direction D1.

The second recess regions NR2 may be aligned to the first recess regions NR1, respectively, in the second direction D2. Since the first and second side surfaces S1 and S2 of the line portion P2 include the first and second recess regions NR1 and NR2, a current density of a current, which is applied to move the domains DM1 and DM2 in the magnetic track line MTL, may be controlled more precisely, and this may make it possible to easily control the positions of the domains DM1 and DM2 in the magnetic track line MTL.

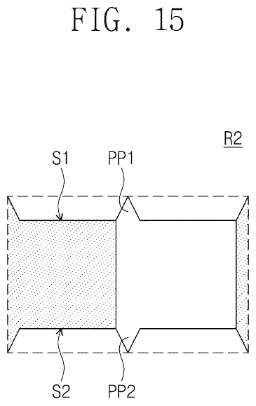

FIG. 14 is a plan view illustrating an example of a magnetic memory device according to some implementations, and FIG. 15 is an enlarged view illustrating an example of a portion ‘R2’ of FIG. 14 according to some implementations. For brevity, features, which are different from the magnetic memory device described with reference to FIGS. 1 to 3, will be mainly described below.

In FIGS. 14 and 15, the line portion P2 of the magnetic track line MTL may have a first side surface S1 and a second side surface S2, which face each other in the second direction D2. The first side surface S1 may include first protruding portions PP1, which are extended from the first side surface S1 toward the outside of the line portion P2 and are spaced apart from each other in the first direction D1. In some implementations, each of the first protruding portions PP1 may protrude from the first side surface S1 in the second direction D2. The second side surface S2 may include second protruding portions PP2, which are extended from the second side surface S2 toward the outside of the line portion P2 and are spaced apart from each other in the first direction D1. In some implementations, each of the second protruding portions PP2 may protrude from the second side surface S2 in an opposite direction of the second direction D2.

The second protruding portions PP2 may be aligned to the first protruding portions PP1, respectively, in the second direction D2. Since the first and second side surfaces S1 and S2 of the line portion P2 include the first and second protruding portions PP1 and PP2, a current density of a current, which is applied to move the domains DM1 and DM2 in the magnetic track line MTL, may be controlled more precisely, and this may make it possible to easily control the positions of the domains DM1 and DM2 in the magnetic track line MTL.

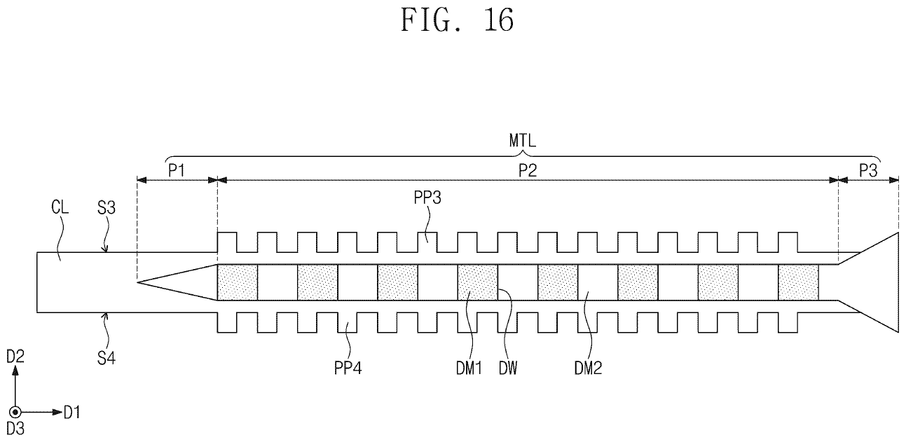

FIG. 16 is a plan view illustrating an example of a magnetic memory device according to some implementations. For brevity, features, which are different from the magnetic memory device described with reference to FIGS. 1 to 3, will be mainly described below.

In FIG. 16, the conductive line CL may have a third side surface S3 and a fourth side surface S4, which face each other in the second direction D2. Below the line portion P2 of the magnetic track line MTL, the third side surface S3 may include third protruding portions PP3, which are extended from the third side surface S3 toward the outside of the conductive line CL and are spaced apart from each other in the first direction D1. In some implementations, each of the third protruding portions PP3 may protrude from the third side surface S3 in the second direction D2. Below the line portion P2 of the magnetic track line MTL, the fourth side surface S4 may include fourth protruding portions PP4, which are extended from the fourth side surface S4 toward the outside of the conductive line CL and are spaced apart from each other in the first direction D1. In some implementations, each of the fourth protruding portions PP4 may protrude from the fourth side surface S4 in the opposite direction of the second direction D2.

The fourth protruding portions PP4 may be aligned to the third protruding portions PP3, respectively, in the second direction D2. Since the third and fourth side surfaces S3 and S4 of the conductive line CL include the third and fourth protruding portions PP3 and PP4, a current density of a current, which is applied to move the domains DM1 and DM2 in the magnetic track line MTL, may be controlled more precisely, and this may make it possible to easily control the positions of the domains DM1 and DM2 in the magnetic track line MTL.

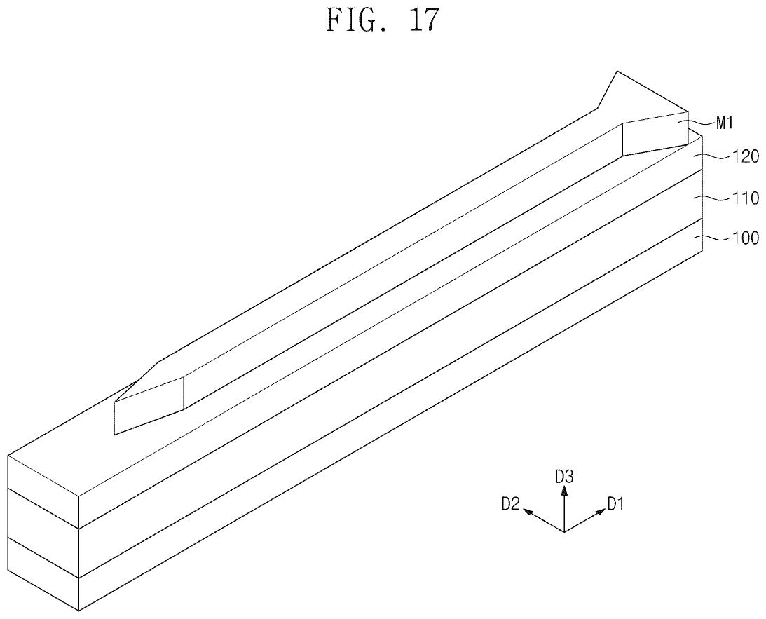

FIGS. 17 to 21 are perspective views schematically illustrating an example of a method of fabricating a magnetic memory device according to some implementations. For brevity, the same element as that in the magnetic memory device described with reference to FIGS. 1 to 3 may be identified by the same reference number without repeating an overlapping description.

In FIG. 17, a conductive layer 110 and a magnetic layer 120 may be sequentially stacked on a substrate 100. The substrate 100 may be a semiconductor substrate (e.g., a silicon substrate, a germanium substrate, or a silicon-germanium substrate). A first mask pattern M1 may be formed on the magnetic layer 120. The first mask pattern M1 may define a planar shape of the magnetic track line MTL described with reference to FIGS. 2, 12, 14, and 16. In an embodiment, the first mask pattern M1 may be a photoresist pattern.

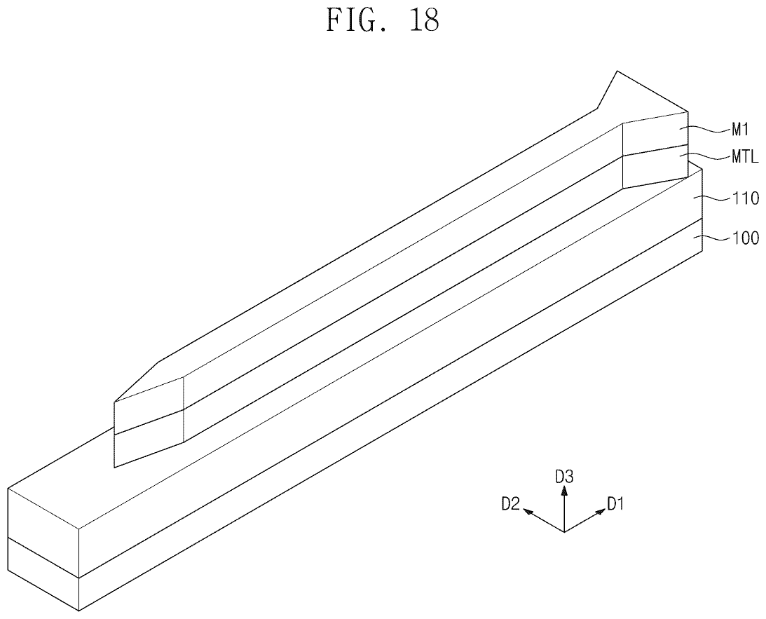

In FIG. 18, the magnetic layer 120 may be etched using the first mask pattern M1 as an etch mask, and as a result, a magnetic track line MTL may be formed. The magnetic track line MTL may have substantially the same features as the magnetic track line MTL described with reference to FIGS. 1 to 16.

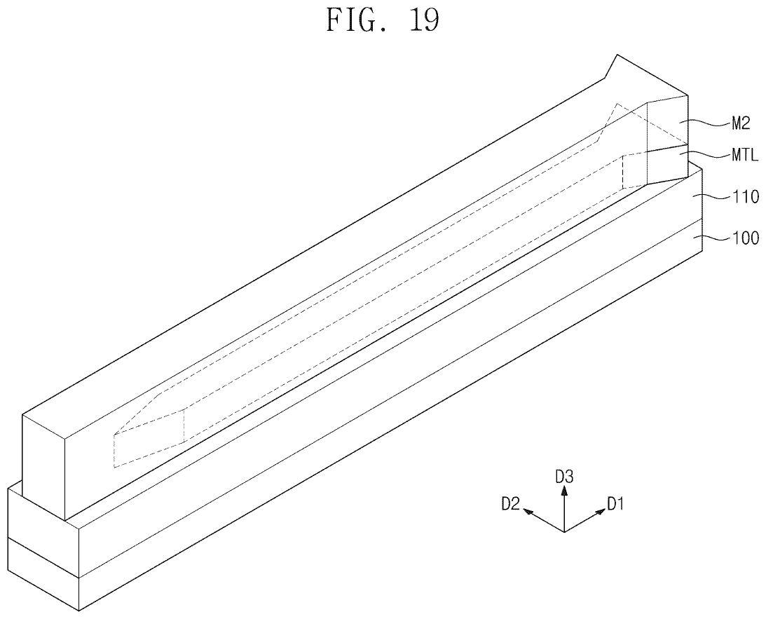

In FIG. 19, the first mask pattern M1 may be removed, after the formation of the magnetic track line MTL. In some implementations, the first mask pattern M1 may be removed by an ashing and/or strip process.

A second mask pattern M2 may be formed on the conductive layer 110 to cover the magnetic track line MTL. The second mask pattern M2 may define a planar shape of the conductive line CL described with reference to FIGS. 2, 12, 14, and 16. In some implementations, the second mask pattern M2 may be a photoresist pattern.

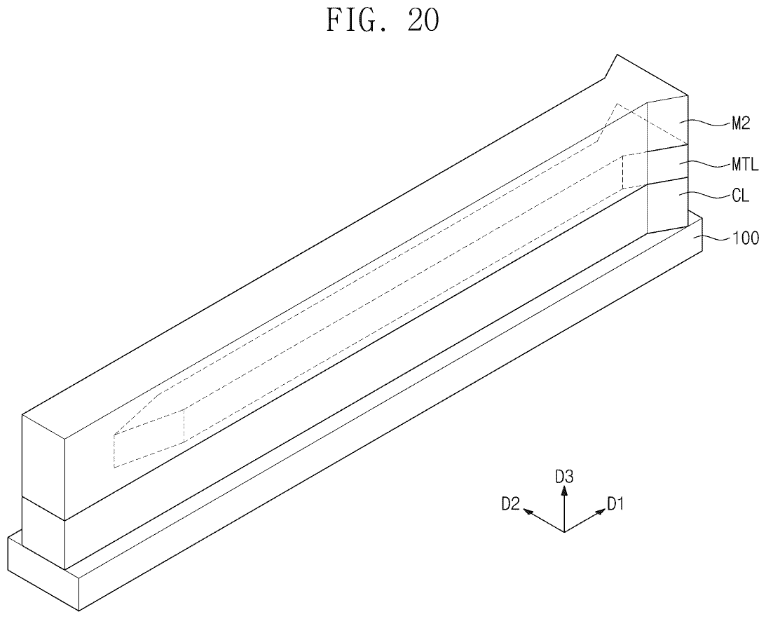

In FIG. 20, the conductive layer 110 may be etched using the second mask pattern M2 as an etch mask to form a conductive line CL. The conductive line CL may be formed to have substantially the same features as the conductive line CL described with reference to FIGS. 1 to 16.

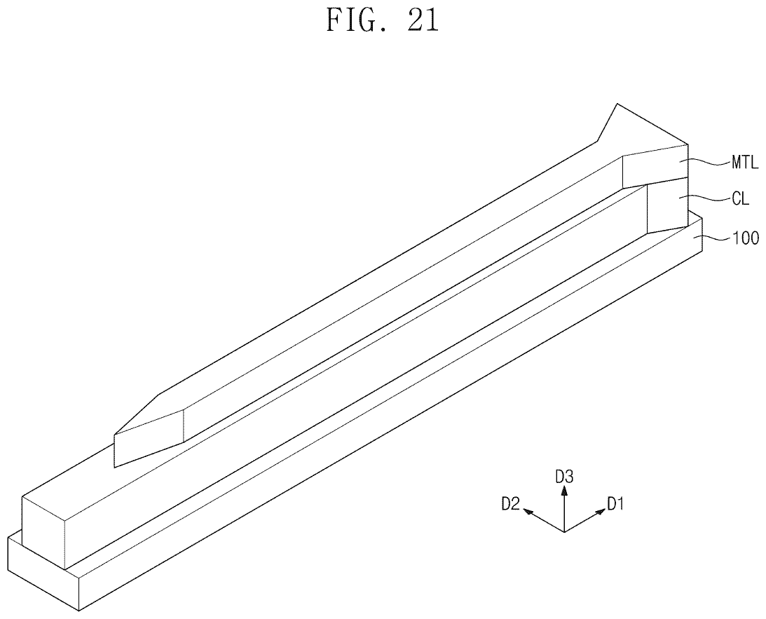

In FIG. 21, the second mask pattern M2 may be removed, after the formation of the conductive line CL. In some implementations, the second mask pattern M2 may be removed by an ashing and/or strip process.

The magnetic memory device fabricated by the above method may have the same structure as described with reference to FIGS. 1 to 16.

According to some implementations, a magnetic track line may include a domain injection portion and a line portion, which is extended from the domain injection portion in a first direction, and the domain injection portion may have a tapered shape in an opposite direction of the first direction. Accordingly, a cross-section area of the domain injection portion may increase as a distance to the line portion of the magnetic track line decreases (i.e., in the first direction). In the case where there is a current flowing through the magnetic track line, a current density (J) of the current may be greater than a critical current density (Jnucl), which is required for domain formation at an end portion of the domain injection portion, and may be reduced to a value that is smaller than the critical current density (Jnucl) as a distance to the line portion of the magnetic track line decreases (i.e., in the first direction). Accordingly, a domain with the same or aligned magnetization direction may be stably formed at the end portion of the domain injection portion of the magnetic track line, and thus, any additional conductive line or a writing device may be unnecessary to form the domain in the magnetic track line (i.e., for a writing operation).

As a result, a writing operation for forming a domain in the magnetic track line may be possible, without an additional conductive line or a writing device, and the magnetic memory device may be configured to allow an easy and stable writing operation for forming the domain in the magnetic track line.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A magnetic memory device, comprising:
a conductive line extending in a first direction; and
a magnetic track line provided on a top surface of the conductive line and extending in the first direction,
wherein the magnetic track line comprises a domain injection portion and a line portion that extends from the domain injection portion in the first direction,
the domain injection portion has a tapered shape in a direction opposite to the first direction,
the conductive line has a linewidth in a second direction,
the first and second directions are parallel to the top surface of the conductive line and are perpendicular to each other, and
below the domain injection portion, a first linewidth of the conductive line remains constant in the direction opposite to the first direction.

2. The magnetic memory device of claim 1,
wherein the domain injection portion has a first width in the second direction, and
the first width decreases in the direction opposite to the first direction.

3. The magnetic memory device of claim 2, wherein the first linewidth of the conductive line is larger than the first width of the domain injection portion.

4. The magnetic memory device of claim 2,
wherein the line portion has a second width in the second direction, and
the second width of the line portion is larger than the first width of the domain injection portion.

5. The magnetic memory device of claim 4,
wherein the magnetic track line further comprises an end portion that extends from the line portion in the first direction,
the end portion has a third width in the second direction, and
the third width of the end portion increases in the first direction.

6. The magnetic memory device of claim 1, wherein a second linewidth of the conductive line below the line portion is equal to the first linewidth of the conductive line.

7. The magnetic memory device of claim 1,
wherein the magnetic track line has a thickness in a third direction perpendicular to the top surface of the conductive line, and
a thickness of the domain injection portion is equal to a thickness of the line portion.

8. The magnetic memory device of claim 7,
wherein the conductive line has a thickness in the third direction, and
a thickness of the conductive line below the domain injection portion is equal to a thickness of the conductive line below the line portion.

9. The magnetic memory device of claim 1, wherein the conductive line is configured to produce a spin orbit torque by a current passing through the conductive line.

10. The magnetic memory device of claim 1, wherein the magnetic track line comprises a plurality of domains that are arranged in the first direction.

11. The magnetic memory device of claim 10, further comprising a magnetic pattern disposed on the line portion of the magnetic track line and a non-magnetic pattern between the line portion and the magnetic pattern,
wherein the magnetic and non-magnetic patterns, along with a corresponding one of the domains, constitute a magnetic tunnel junction.

12. The magnetic memory device of claim 1,
wherein the line portion of the magnetic track line has side surfaces that face each other in the second direction,
each of the side surfaces of the line portion comprises recess regions that are recessed into the line portion, and
the recess regions are spaced apart from each other in the first direction.

13. The magnetic memory device of claim 1,
wherein the line portion of the magnetic track line has side surfaces that face each other in the second direction,
each of the side surfaces of the line portion comprises protruding portions that protrude from the line portion, and
the protruding portions are spaced apart from each other in the first direction.

14. The magnetic memory device of claim 1,
wherein the conductive line has side surfaces that face each other in the second direction,
each of the side surfaces of the conductive line comprise protruding portions that protrude from the conductive line, and
the protruding portions are spaced apart from each other in the first direction.

15. A magnetic memory device, comprising:
a conductive line extended in a first direction; and
a magnetic track line provided on a top surface of the conductive line and extended in the first direction,
wherein the magnetic track line comprises a domain injection portion and a line portion that extends from the domain injection portion in the first direction,
the magnetic track line has a width in a second direction,
the first and second directions are parallel to the top surface of the conductive line and are perpendicular to each other,
a first width of the domain injection portion decreases as a distance from the line portion increases,
the conductive line has a linewidth in the second direction, and
below the domain injection portion, a first linewidth of the conductive line is larger than the first width of the domain injection portion.

16. The magnetic memory device of claim 15, wherein a second width of the line portion is larger than the first width of the domain injection portion.

17. The magnetic memory device of claim 16, wherein a second linewidth of the conductive line below the line portion is equal to the first linewidth of the conductive line.

18. The magnetic memory device of claim 15, wherein the magnetic track line comprises a plurality of domains that are arranged in the first direction, and domain walls formed between the domains.

19. The magnetic memory device of claim 18, wherein the conductive line is configured to produce a spin orbit torque by a current passing through the conductive line.

20. The magnetic memory device of claim 19, further comprising a magnetic pattern on the line portion of the magnetic track line and a non-magnetic pattern between the line portion and the magnetic pattern,
wherein the magnetic and non-magnetic patterns, along with a corresponding one of the domains, constitute a magnetic tunnel junction.
